(19) United States
(12) Patent Application Publication
(10) Pub. No.: US 2018/0014426 A1
(43) Pub. Date: Jan. 11, 2018

(54) PCB MODULE WITH MULTI-SURFACE HEAT DISSIPATION STRUCTURE, HEAT DISSIPATION PLATE USED IN PCB MODULE, MULTI-LAYER PCB ASSEMBLY, AND MODULE CASE

(71) Applicant: Ku Yong KIM, Incheon (KR)

(72) Inventor: Ku Yong KIM, Incheon (KR)

(21) Appl. No.: 15/358,742

(22) Filed: Nov. 22, 2016

(30) Foreign Application Priority Data
Jul. 5, 2016 (KR) 10-2016-0084757

(51) Int. Cl. H05K 7/20; H05K 1/02; H05K 1/18; H05K 5/00; H05K 1/14

(52) U.S. Cl. CPC H05K 7/205; H05K 5/0008; H05K 1/144; H05K 1/181; H05K 1/0204; H05K 2201/042; H05K 2201/09063; H05K 2201/10242

(57) ABSTRACT

A PCB module having a multi-surface heat dissipation structure is provided. The PCB module includes: a multi-layer PCB assembly which includes a heat dissipation plate having electrical insulating properties, and an upper PCB and a lower PCB attached to a top surface and a bottom surface of the heat dissipation plate, respectively; an upper case for covering a top surface of the multi-layer PCB assembly; and a lower case for covering a bottom surface of the multi-layer PCB assembly, and the heat dissipation plate includes; a first heat pole which is thermally in contact with an electronic circuit element mounted on the upper PCB or the lower PCB; and a second heat pole which is thermally in contact with an inner surface of at least one of the upper and lower cases.

### CROSS-REFERENCE TO RELATED PATENT APPLICATION

This application claims priority from Korean Patent Application No. 10-2016-0084757, filed on Jul. 5, 2016 in the Korean Intellectual Property Office, the disclosure of which is incorporated herein by reference in its entirety.

### FIELD

Apparatuses and methods consistent with the exemplary embodiments relate to a multi-layer printed circuit board (PCB) module, and more particularly, to a PCB module with a multi-surface heat dissipation structure, which can effectively discharge heat generated from a multi-layered PCB to the outside, a heat dissipation plate used in the PCB module, a multi-layer PCB assembly, and a module case.

### BACKGROUND

In a normal structure of a multi-layer PCB on which a power semiconductor module package is mounted, a plurality of PCBs 1 are stacked one on another as shown in FIG. 1, and each of the PCBs 1 has circuit patterns 1b and 1c, made of copper, printed on opposite surfaces of a substrate 1a like FR-4, CEM-1, CEM-3, Al METAL-PCB. In addition, the PCBs are electrically insulated from one another by prepreg 2. An electronic circuit element such as an IC chip, a power semiconductor module package, or the like is mounted on the circuit pattern of the outermost PCB, and a heat dissipation structure is additionally installed on the surface of the multi-layer PCB structure to discharge heat generated from such an electronic circuit element to the outside.

According to such a normal multi-layer PCB structure, however, since the PCBs are stacked one on another in sequence, heat generated from the circuit pattern of the PCB located inside is not efficiently discharged, and also, there are disadvantages that the structure of the PCB module becomes complicated due to the heat dissipation structure installed on the surface of the multi-layer PCB, and the volume increases.

### SUMMARY

One or more exemplary embodiments may overcome the above disadvantages and other disadvantages not described above. However, it is understood that one or more exemplary embodiment are not required to overcome the disadvantages described above, and may not overcome any of the problems described above.

One or more exemplary embodiments provide a multi-layer PCB module structure which can enhance a cooling efficiency by rapidly discharging heat generated from the multi-layer PCB to the outside through a case, and can realize a compact and slim size of a PCB module.

According to an aspect of an exemplary embodiment, there is provided a PCB module having a multi-surface heat dissipation structure, including: a multi-layer PCB assembly which includes a heat dissipation plate having electrical insulating properties, and an upper PCB and a lower PCB attached to a top surface and a bottom surface of the heat dissipation plate, respectively; an upper case for covering a top surface of the multi-layer PCB assembly; and a lower case for covering a bottom surface of the multi-layer PCB assembly, wherein the heat dissipation plate includes; a first heat pole which is thermally in contact with an electronic circuit element mounted on the upper PCB or the lower PCB; and a second heat pole which is thermally in contact with an inner surface of at least one of the upper and lower cases.

According to an aspect of another exemplary embodiment, there is provided a heat dissipation plate having electrical insulating properties, which is used in a multi-layer PCB assembly having a multi-surface heat dissipation structure, the heat dissipation plate including: a first heat pole of a first height which protrudes from a top or bottom surface of the heat dissipation plate; and a second heat pole of a second height which protrudes from the top or bottom surface of the heat dissipation plate, wherein the heat dissipation plate is interposed between an upper PCB including a first layer circuit pattern of the multi-layer PCB assembly and a lower PCB including a second layer circuit pattern, wherein the first heat pole is thermally in contact with an electronic circuit element mounted on the upper PCB or lower PCB, and wherein the second heat pole is thermally in contact with an inner surface of a case for covering the top surface or bottom surface of the multi-layer PCB assembly.

According to an aspect of another exemplary embodiment, there is provided a multi-layer PCB assembly which is used in a PCB module having a multi-surface heat dissipation structure, the multi-layer PCB assembly including: an upper PCB which includes a first layer circuit pattern of the multi-layer PCB assembly; a lower PCB which includes a second layer circuit pattern of the multi-layer PCB assembly; and a heat dissipation plate 40 having electrical insulating properties, which is interposed between the upper PCB and the lower PCB, and wherein the heat dissipation plate includes a first heat pole which is thermally in contact with an electronic circuit element mounted on the upper or lower PCB; and a second heat pole which is thermally in contact with a surface of a case for covering the upper or lower PCB.

According to an aspect of another exemplary embodiment, there is provided a case having electrical insulating properties and thermal conductivity, for covering a multi-layer PCB assembly having a multi-surface heat dissipation structure, the case including an upper case for accommodating the top and a part of the side surfaces of the multi-layer PCB assembly; and a lower case for accommodating the bottom and a part of the side surfaces of the multi-layer PCB assembly, wherein the multi-layer PCB assembly includes: a heat dissipation plate having electrical insulating properties; and an upper PCB and a lower PCB attached to the top and bottom surfaces of the heat dissipation plate, respectively, wherein each of the upper and lower cases includes a first contact region which is thermally in contact with an electronic circuit element mounted on the upper or lower PCB, and a second contact region which is thermally in contact with a heat pole protruding from the heat dissipation plate.

According to an aspect of another exemplary embodiment, there is provided a PCB module having a multi-surface heat dissipation structure, including: a multi-layer PCB assembly which includes a heat dissipation plate having electrical insulating properties, and an upper PCB and a lower PCB attached to a top surface and a bottom surface of the heat dissipation plate, respectively; an upper case for covering a top surface of the multi-layer PCB assembly; and a lower case for covering a bottom surface of the multi-layer PCB assembly, wherein the heat dissipation plate includes a first heat pole which is thermally in contact with an electronic circuit element mounted on the upper PCB or the lower PCB, and wherein at least one of the supper and lower cases includes a second heat pole which is formed on the inner surface of the at least one and is thermally in contact with the heat dissipation plate.

According to exemplary embodiments of the present disclosure, the heat dissipation plate is interposed between the upper and lower PCBs and is configured to be thermally and directly in contact with the cases, such that heat generated from the PCBs can be rapidly discharged to the outside and a compact and slim PCB module can be realized.

Additional and/or other aspects and advantages of the invention will be set forth in part in the description which follows and, in part, will be obvious from the description, or may be learned by practice of the invention.

### BRIEF DESCRIPTION OF THE DRAWINGS

The above and other features and advantages will become more apparent by describing in detail exemplary embodiments with reference to the attached drawings in which:

FIG. 1 is a cross section view showing a layered structure of a related-art multi-layer PCB;

FIG. 2 is a perspective view showing a multi-layer PCB module according to an exemplary embodiment of the present disclosure;

FIG. 3 is an exploded perspective view showing a multi-layer PCB module according to an exemplary embodiment;

FIG. 4 is a view to illustrate an exemplary cross sectional structure of a PCB module according to an exemplary embodiment;

FIG. 5 is a bottom perspective view of a heat dissipation plate according to an exemplary embodiment;

FIG. 6 is a bottom perspective view of an upper case according to an exemplary embodiment;

FIG. 7 is a view to illustrate an exemplary cross sectional structure of a PCB module according to another exemplary embodiment;

FIG. 8 is a view to illustrate an exemplary cross sectional structure of a PCB module according to another exemplary embodiment; and

FIG. 9 is a view to illustrate an exemplary cross sectional structure of a PCB module according to another exemplary embodiment.

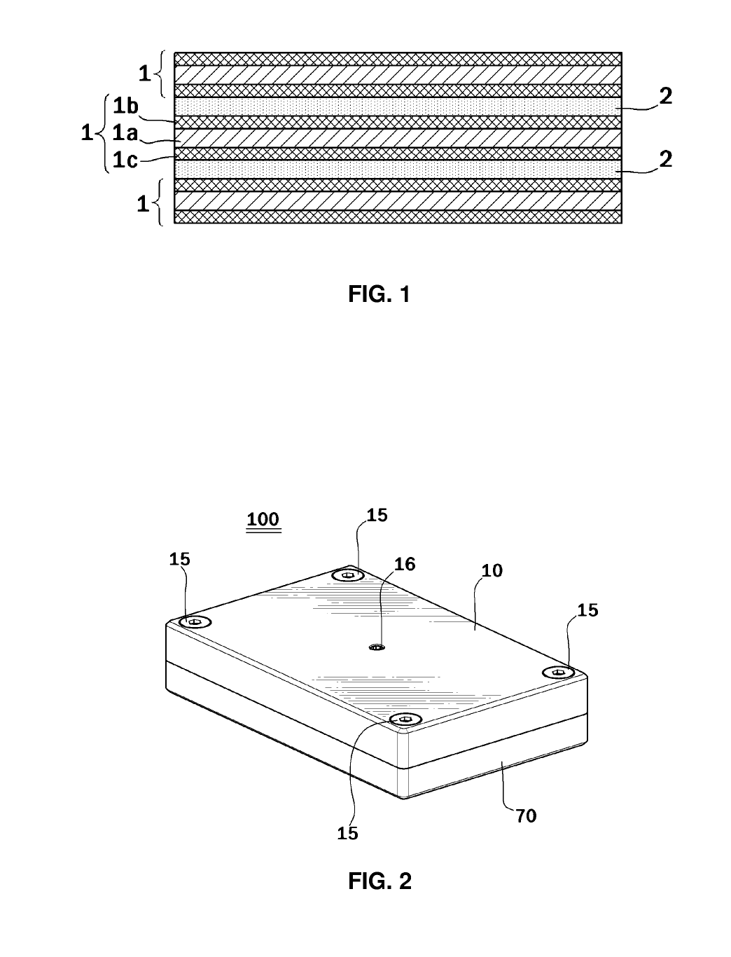

### DETAILED DESCRIPTION

Exemplary embodiments will now be described more fully with reference to the accompanying drawings to clarify aspects, other aspects, features and advantages of the inventive concept. The exemplary embodiments may, however, be embodied in many different forms and should not be construed as limited to the exemplary embodiments set forth herein. Rather, the exemplary embodiments are provided so that this disclosure will be thorough and complete, and will fully convey the scope of the application to those of ordinary skill in the art. It will be understood that when an element is referred to as being “on” another element, the element can be directly on another element or intervening elements.

The terms used herein are for the purpose of describing particular exemplary embodiments only and are not intended to be limiting. As used herein, the singular forms are intended to include the plural forms as well, unless the context clearly indicates otherwise. It will be further understood that the terms “comprises” and/or “comprising,” when used in this specification, do not preclude the presence or addition of one or more other components.

Hereinafter, exemplary embodiments will be described in greater detail with reference to the accompanying drawings. The matters defined in the description, such as detailed construction and elements, are provided to assist in a comprehensive understanding of the exemplary embodiments. However, it is apparent that the exemplary embodiments can be carried out by those of ordinary skill in the art without those specifically defined matters. In the description of the exemplary embodiment, certain detailed explanations of related art are omitted when it is deemed that they may unnecessarily obscure the essence of the inventive concept.

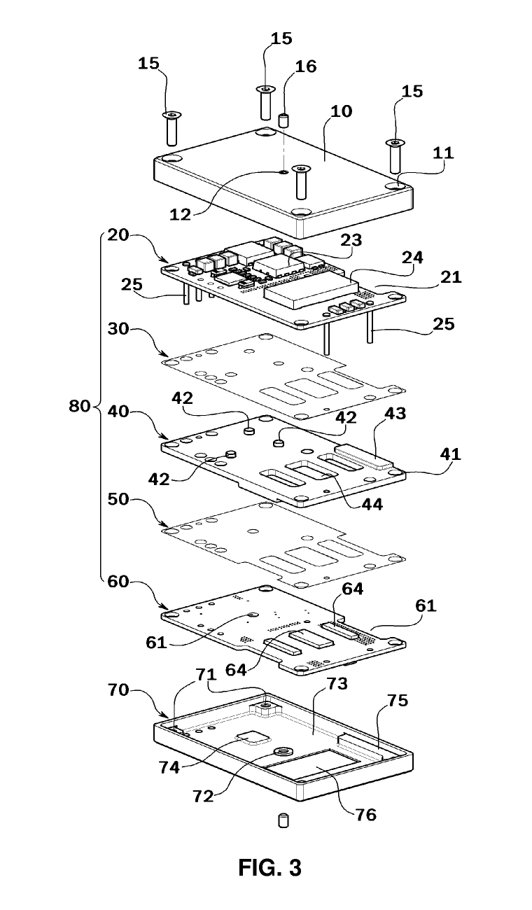

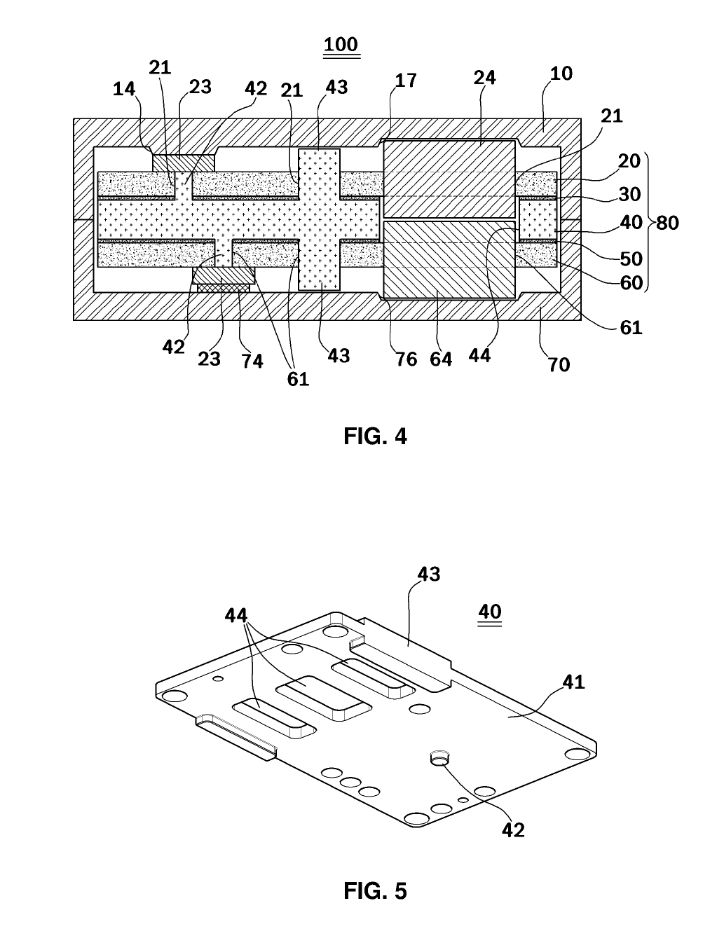

A multi-layer PCB module 100 according to an exemplary embodiment will be described with reference to FIGS. 2 to 4. FIG. 2 is a perspective view of a multi-layer PCB module 100 according to an exemplary embodiment of the present disclosure, and FIG. 3 is an exploded perspective view. FIG. 4 is a view to illustrate an exemplary cross sectional structure of the multi-layer PCB module 100 according to an exemplary embodiment. However, FIG. 4 schematically illustrates elements to easily explain the elements of the PCB module 100, and the structure in FIG. 4 is not identical to the structure of FIG. 3.

Referring to FIG. 2, the multi-layer PCB module 100 according to an exemplary embodiment may be packaged in a substantially hexahedral shape, and in one embodiment, the multi-layer PCB module 100 may be formed by connecting an upper case 10 and a lower case 70. The upper case 10 and the lower case 70 may be connected with each other by means of fastening means 15 and 16 such as a bolt. Although not shown in FIG. 2, a plurality of pins 25 (see FIG. 3) may protrude toward the outside of the multi-layer PCB module 100 and the multi-layer PCB module 100 may be electrically connected with an external electronic device through the pins 25.

Referring to FIGS. 3 and 4, the PCB module 100 may have a structure in which the upper case 10 and the lower case 70 are connected with each other with a multi-layer PCB assembly 80 disposed therebetween. The multi-layer PCB assembly 80 may include a heat dissipation plate 40 having electrical insulating properties, and an upper PCB 20 and a lower PCB 60 which are connected to the top surface and the bottom surface of the heat dissipation plate 40, respectively.

The upper PCB 20 may include a circuit pattern of at least one layer and may be a normal substrate having a multi-layer circuit pattern. In one embodiment, the upper PCB 20 may be formed of a substrate such as FR-4, CEM-1, CEM-3, Al Metal-PCB, or the like, and the type of the substrate is not limited to these.

The upper PCB 20 may have a penetrating portion 21 formed therethrough to allow heat poles 42 and 43 of the heat dissipation plate 40 to penetrate therethrough. The shape or location of the penetrating portion 21 may vary according to a circuit design of the PCB 20 in a specific exemplary embodiment. A plurality of electronic circuit elements 23 and 24 may be mounted on the top surface of the substrate of the upper PCB 20, and one or more pins 25 may vertically protrude from the surface of the substrate and may be electrically connected with an external electronic device. Herein, the “electronic circuit element” may refer to one of various passive elements or active elements and various types of IC chips integrating the passive or active elements thereinto.

The lower PCB 60 has the same or similar structure as or to that of the upper PCB 20. The lower PCB 60 includes a circuit pattern of at least one layer and may normally have a multi-layer circuit pattern. The lower PCB 60 may have a penetrating portion 61 formed therethrough to allow the heat poles 42 and 43 of the heat dissipation plate 40 to penetrate therethrough, and the shape or locations of the penetrating portion 61 may vary according to a circuit design of the PCB 60. A plurality of electronic circuit elements 64 may be mounted on the surface of the substrate of the lower PCB 60.

The upper PCB 20 and the lower PCB 60 are connected with each other with the heat dissipation plate 40 disposed therebetween, and thereby form the multi-layer PCB assembly 80 as one unit. In this case, an insulation layer 30 having electrical insulating properties may be interposed between the upper PCB 20 and the heat dissipation plate 40, and an insulation layer 50 having electrical insulating properties may be interposed between the lower PCB 60 and the heat dissipation plate 40. The insulation layers 30 and 50 may be made of a material having electrical insulating properties but not having thermal barrier properties or having low thermal barrier properties, and accordingly, heat generated from the upper or lower PCBs 20 and 60 may be smoothly transmitted to the heat dissipation plate 40. In one embodiment, the insulation layers 30 and 50 may be made of prepreg.

Hereinbelow, the heat dissipation plate 40 will be described with reference to FIGS. 3 to 5.

FIG. 5 is a bottom perspective view of the heat dissipation plate according to an exemplary embodiment, and illustrates the heat dissipation plate 40 of FIG. 3 as viewed from above.

The heat dissipation plate 40 may be disposed between the upper PCB 20 and the lower PCB 60 to absorb heat generated from the PCBs 20 and 60 via various paths and discharge the heat to the cases 10 and 70. To achieve this, for example, the heat dissipation plate 40 may be made of a material having high thermal conductivity, such as copper (Cu), aluminum (Al), silicon carbide (SiC), aluminum nitride (AlN), or the like. In one embodiment, the heat dissipation plate 40 having high thermal conductivity while having electrical insulating properties and may be produced by anodizing a plate of aluminum.

The heat dissipation plate 40 may include one or more heat poles 42 and 43 formed on the top surface and the bottom surface thereof. The heat poles 42 and 43 may be protrusions vertically protruding from the top surface and the bottom surface of the heat dissipation plate 40 and formed in a pillar shape including a circular or polygonal cross section.

In the illustrated embodiment, the heat poles may include a first heat pole 42 and a second heat pole 43. The first heat pole 42 is a protrusion protruding from the surface of the heat dissipation plate 40 and having a first predetermined height. In an embodiment, as shown in FIG. 4, the first heat pole 42 protrudes to penetrate through penetrating portions 21 and 61 of the PCBs 20 and 60 and to be flush with the surface of the PCB when the upper and lower PCBs 20 and 60 are connected with the heat dissipation plate 40, and accordingly, the first heat pole 42 is thermally in contact with the electronic circuit element 23 mounted on the surface of the upper or lower PCB 20 or 60.

The second heat pole 43 is a protrusion protruding from the surface of the heat dissipation plate 40 and having a second predetermined height, and normally is higher than the first heat pole 42. As shown in FIG. 4, the second heat pole 43 protrudes to penetrate through the penetrating portions 21 and 61 of the PCBs 20 and 60 and to have a height to be thermally in contact with the inner surfaces of the cases 10 and 70 when the upper and lower PCBs 20 and 60 are connected with the upper and lower cases 10 and 70.

According to the configuration of the first and second heat poles 42 and 43, heat generated from the electronic circuit element 23 is absorbed into the first heat pole 42 and transmitted to the heat dissipation plate 40. Then, the heat is transmitted to the cases 10 and 70 through the second heat pole 43 and discharged to the outside.

In the illustrated embodiment, the heat dissipation plate 40 may further include one or more penetrating regions 44 penetrating through the top and bottom surfaces of the heat dissipation plate 40. The penetrating regions 44 may be provided to provide a contact point or a contact region where the electronic circuit elements mounted on the upper PCB 20 and the lower PCB 60 are physically or electrically in contact with each other.

For example, referring to FIGS. 3 and 4, each of the electronic circuit element 24 mounted on the upper PCB 20 and the electronic circuit element 64 mounted on the lower PCB 60 is a part of a coil, and the two circuit elements 24 and 64 are physically or electrically brought into contact with each other through the penetrating regions 44 of the heat dissipation plate 40 when the upper PCB 20 and the lower PCB 60 are connected with each other with the heat dissipation plate 40 being interposed therebetween, such that the circuit elements 24 and 64 serve as coils.

Therefore, according to an exemplary embodiment, at least a part of the electronic circuit elements mounted on the upper PCB 20 or the lower PCB 60 does not perform a specific function until the upper PCB 20 and the lower PCB 60 are connected with each other and are assembled into the multi-layer PCB assembly 80. According to the present disclosure, the multi-layer PCB structure is divided into the upper PCB and the lower PCB, the heat dissipation plate 40 is interposed between the PCBs, and then the upper and lower PCBs are assembled with each other, such that the multi-layer PCB assembly 80 having the heat dissipation structure of the present disclosure therein can be realized.

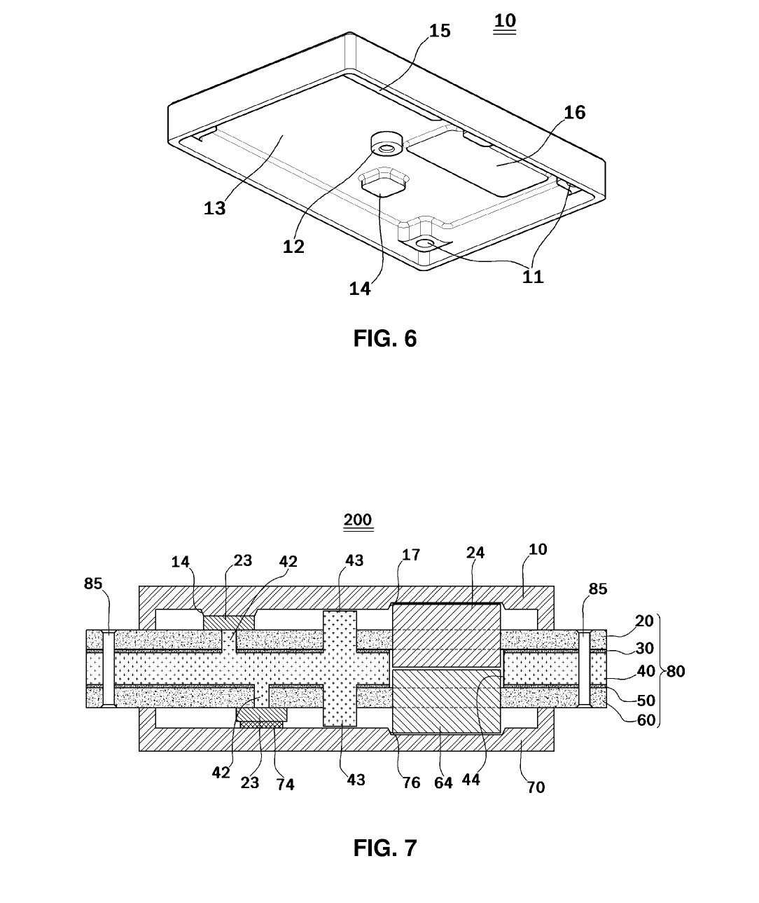

Referring to FIGS. 3, 4, and 6, the upper and lower cases 10 and 70 will be described. FIG. 6 is a bottom perspective view of the upper case 10 according to an exemplary embodiment, and illustrates the upper case 10 of FIG. 3 as viewed from the bottom.

The upper and lower cases 10 and 70 are connected with each other to cover the surfaces of the upper PCB 20 and the lower PCB 60, respectively, and absorb heat generated from the respective PCBs 20 and 60 and heat transmitted through the heat dissipation plate 40 and discharge the heat to the outside. The upper and lower cases 10 and 70 may perform a function as a heat sink, or may be connected with an external heat sink and transmit heat to the external heat sink.

To achieve this, the upper and lower cases 10 and 70 may be made of a material having high thermal conductivity, such as copper (Cu), aluminum (Al), silicon carbide (SiC), aluminum nitride (AlN), or the like. In one embodiment, the cases 10 and 70, which have high thermal conductivity while having electrical insulating properties, may be produced by anodizing a case of aluminum.

The upper case 10 covers the top and a part of the side surfaces of the multi-layer PCB assembly 80, and the lower case 70 may cover the bottom and a part of the side surfaces of the multi-layer PCB assembly 80.

The upper and lower cases 10 and 70 may include first contact regions 14, 16, 17, 74, and 76 which are formed on the inner surfaces of the cases to be thermally in contact with the electronic circuit elements 23, 24, and 64 mounted on the upper PCB 20 or the lower PCB 60.

For example, the first contact regions 14 and 16 on the upper case 10 are in contact with the electronic circuit element 23 mounted on the upper PCB 20, and, for example, the contact regions 14 and 16 shown in FIG. 6 are protrusions protruding from the inner surface 13 of the case 10. The contact regions 14 and 16 may be integrally formed with the inner surface 13 of the case 10 and extend therefrom in the form of a protrusion as shown in FIG. 4.

In another example, another contact region 17 from among the first contact regions may be a recess which is lower than the inner surface of the case 10, and, for example, may be in contact with the electronic circuit element 24 which has a relatively large size like a coil. Since whether the first contact region is the protrusion or recess is related to the volume (or height) of an electronic circuit element in contact therewith, the shapes, number, or locations of the first contact regions may vary according to a specific embodiment.

Likewise, referring to FIG. 3, the first contact regions 74 and 76 may be formed on the lower case 70. In the illustrated embodiment, the contact region 74 may be formed in the form of a protrusion and the contact region 76 may be formed in the form of a recess. In addition, as shown in FIGS. 3 and 4, the contact region 74 in the form of a protrusion may be formed by attaching a member made of a different material from the lower case 70 to the surface 73 of the lower case 70, and for example, may be implemented by using a thermal conductive member such as a thermal pad.

In addition, as shown in FIGS. 3 and 6, the upper and lower cases 10 and 70 may further include second contact regions 15 and 75 which are formed on the inner surfaces of the cases to be thermally in contact with the second heat pole 43 protruding from the heat dissipation plate 40. The second contact regions 15 and 17 may protrude from the inner surfaces 13 and 73 of the cases 10 and 70 to have a step or may be flush with the inner surfaces 13 and 73 according to the height or shape of the second heat pole 43, and the shapes, number, and locations of the second contact regions may vary according to a specific embodiment.

According to the multi-layer PCB assembly 80 and the cases 10 and 70 enclosing the same as described above, heat generated from the PCBs may be discharged to the outside of the PCB module 100 via the following paths.

First, heat generated from the electronic circuit elements 23, 24, and 64 mounted on the upper PCB 20 and the lower PCB 60 is transmitted to the first heat pole 42 of the heat dissipation plate 40. Since the first heat pole 42 is thermally and directly in contact with the electronic circuit elements 23, 24, and 64 through the PCBs 20 and 60, the first heat pole 42 can more rapidly absorb heat from the electronic circuit element in comparison to related-art methods.

Second, the heat absorbed by the heat dissipation plate 40 from the upper and lower PCBs 20 and 40 is transmitted to the upper and lower cases 10 and 70 through the second heat pole 43, and is discharged to the outside of the PCB module 100. Since the second heat pole 43 is thermally and directly in contact with the upper and lower cases 10 and 70 through the substrates of the PCBs 20 and 60, the second heat pole 43 can more rapidly discharge the heat of the heat dissipation plate 40 to the cases 10 and 70 in comparison to related-art methods.

Third, heat generated from the electronic circuit elements mounted on the upper PCB 20 and the lower PCB 60 may be transmitted to the cases 10 and 70 through the first contact regions 14, 16, 17, 74, and 76 of the upper and lower cases 10 and 70 as well as through the first heat pole 42. As shown in FIG. 4, since one surface of the electronic circuit element is in contact with the first heat pole 42, the heat is discharged to the first heat pole 42. On the other hand, since the opposite surface of the electronic circuit element is thermally and directly in contact with the first contact regions 14, 17, 74, 76 of the cases 10 and 70, the heat is discharged through the first contact regions. That is, since both surfaces of the electronic circuit element mounted on the PCBs 20 and 60 are in contact with a heat transmission member, the heat can be more rapidly discharged in comparison to related-art methods.

As described above, the PCB module 100 has a multi-surface heat dissipation structure which can discharge heat via various paths due to the configuration of the multi-layer PCB assembly 80 and the cases 10 and 70. In addition, there is an additional effect that the inner space of the PCB module 100 can be greatly reduced and thus the compact and slim PCB module can be produced.

For example, a TO-220 chip may be mounted as the electronic circuit element to be mounted on the PCBs 20 and 60. In this case, according to a related-art method, the TO-220 chip may be mounted on a multi-layer PCB substrate in an upright position, and heat generated from the chip may be transmitted to a case through an inner space of the case (filled with air) and discharged to the outside of the case.

However, according to exemplary embodiments of the present disclosure, the TO-220 chip may be mounted on the PCBs 20 and 60, being laid in a horizontal position, with one side surface thereof being in contact with the first heat pole 42 and the other side surface being in contact with the first contact regions 14 and 74. Accordingly, since the chip can be laid in the horizontal position, the inner empty space of the PCB module 100 can be greatly reduced and the thickness of the module 100 can be reduced. Heat generated from the chip can be more rapidly discharged through the heat dissipation plate 40 and the cases 10 and 70 located on both surfaces of the chip.

Therefore, when the PCB module of the present disclosure is applied to a high-power element package, the power elements can be integrated. For example, the inventor of the present disclosure conducted an experiment by applying the configuration of the PCB module 100 of the present disclosure to an on board charger (OBC) for a vehicle. As a result of the experiment, the volume of a 13 KW OBC device using a related-art multi-layer PCB structure was 20 liters, and the volume was greatly reduced to 6 liters when the configuration of the PCB module of the present disclosure was applied. In addition, it was revealed that the heat dissipation effect increased by 30 to 40% in comparison to the related-art method.

Hereinafter, alternative embodiments of the PCB module 100 according to the present disclosure will be described with reference to FIGS. 7 and 9.

FIG. 7 is a view schematically showing an exemplary cross sectional structure of a PCB module 200 according to another exemplary embodiment. The inner structure of the module 200 of FIG. 7 is substantially the same as or similar to that of the PCB module 100 of FIG. 4, and thus a detailed description thereof is omitted. However, in the embodiment of FIG. 7, the upper and lower cases 10 and 70 of the PCB module 200 do not cover the side surfaces of the multi-layer PCB assembly 80 and cover only the top surface and the bottom surface of the multi-layer PCB assembly 80.

For example, penetrating holes 85 may be formed through the regions of the multi-layer PCB assembly 80 which are not covered by the cases 10 and 70 as shown in FIG. 7, and the multi-layer PCB assembly 80 may be electrically or physically connected with an external electronic device outside the PCB module 200 through the penetrating holes 85.

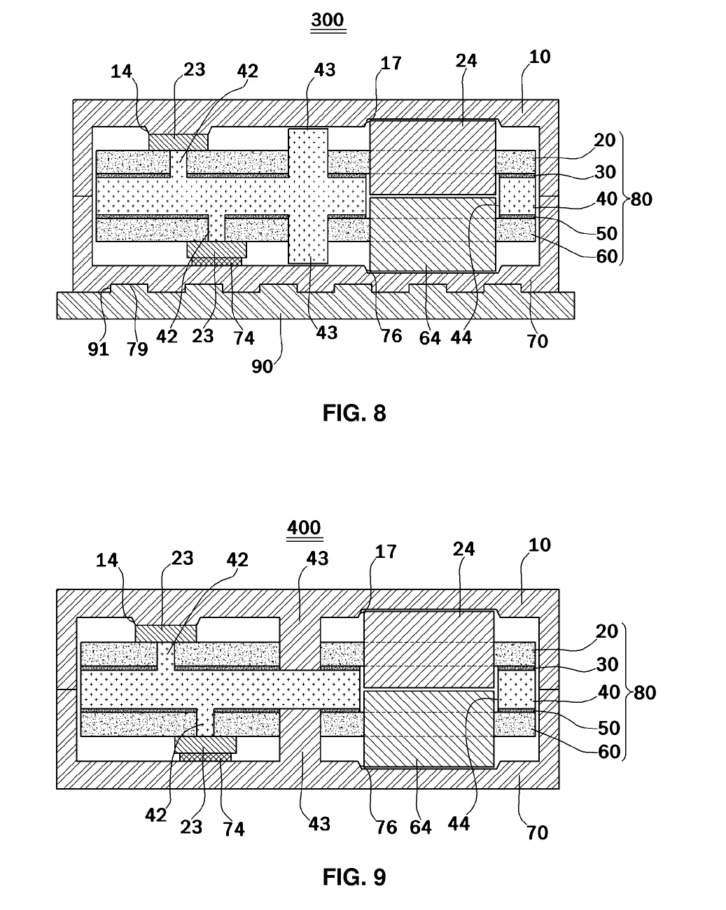

FIG. 8 is a view schematically showing an exemplary cross sectional structure of a PCB module 300 according to another exemplary embodiment. The inner structure of the module 300 of FIG. 8 is substantially the same as or similar to that of the PCB module 100 of FIG. 4, and thus a detailed description thereof is omitted. However, in the embodiment of FIG. 8, a first concavo-convex shape 79 is formed on the outer surface of the lower case 70 of the PCB module 300, and an additional heat dissipation structure 90 is attached to the outer surface of the lower case 70. A second concavo-convex shape 91 may be formed on the surface of the heat dissipation structure 90 to be engaged with the first concavo-convex shape 79. According to this configuration, the heat of the lower case 70 can be more rapidly discharged to the outside.

Although the heat dissipation structure 90 is attached to the lower case 70 in FIG. 8, the heat dissipation structure 90 may be attached to the upper case 10. In addition, although the concavo-convex shapes 79 and 91 are formed between the cases 10 and 70 and the heat dissipation structure 90, the concavo-convex shapes 79 and 91 may be omitted.

FIG. 9 is a view schematically showing an exemplary cross sectional structure of a PCB module 400 according to another exemplary embodiment. The inner structure of the module 400 of FIG. 9 is substantially the same as or similar to that of the PCB module 100 of FIG. 4. However, in the embodiment of FIG. 9, a heat pole 43 may be formed on the inner surface of at least one of the upper and lower cases 10 and 70 to be thermally in contact with the heat dissipation plate 40. That is, the heat pole 43 for connecting the cases 10 and 70 and the heat dissipation plate 40 may be formed on the cases 10 and 70 in the PCB module 400 of FIG. 9.

Therefore, the heat pole 43 for thermally connecting the heat dissipation plate 40 and the cases 10 and 70 may be formed on any side of the heat dissipation plate and the case, and in an alternative embodiment, the heat pole 43 may be formed as an independent element separate from the heat dissipation plate 40 or the cases 10 and 70 and then both ends of the heat pole 43 may be connected to the heat dissipation plate and the cases.

While the invention has been shown and described with reference to certain preferred embodiments thereof, it will be understood by those skilled in the art that various changes in form and details may be made therein without departing from the spirit and scope of the invention as defined by the appended claims. Therefore, the scope of the invention is defined not by the detailed description of the invention but by the appended claims, and all differences within the scope will be construed as being included in the present invention.

What is claimed is:

1. A PCB module having a multi-surface heat dissipation structure, the PCB module comprising:
a multi-layer PCB assembly which comprises a heat dissipation plate having electrical insulating properties, and an upper PCB and a lower PCB attached to a top surface and a bottom surface of the heat dissipation plate, respectively;
an upper case for covering a top surface of the multi-layer PCB assembly; and
a lower case for covering a bottom surface of the multi-layer PCB assembly,
wherein the heat dissipation plate comprises:
a first heat pole which is thermally in contact with an electronic circuit element mounted on the upper PCB or the lower PCB; and
a second heat pole which is thermally in contact with an inner surface of at least one of the upper and lower cases.

2. The PCB module of claim 1, wherein a contact region is formed on the inner surface of at least one of the upper case and the lower case to be thermally in contact with the electronic circuit element mounted on the upper PCB or lower PCB.

3. The PCB module of claim 2, wherein the contact region comprises a thermal pad.

4. The PCB module of claim 1, wherein one or more penetrating regions are formed through the top and bottom surfaces of the heat dissipation plate, and
wherein the multi-layer PCB assembly comprises one or more contact points or contact regions where the upper PCB and the lower PCB are physically or electrically in contact with each other through the penetrating regions of the heat dissipation plate.

5. The PCB module of claim 1, wherein one or more penetrating portions are formed in at least one of the upper PCB and the lower PCB to allow the first heat pole or the second heat pole to be inserted therethrough, and
wherein the first heat pole protrudes to be flush with the surface of the upper PCB or the lower PCB, and the second heat pole protrudes to have a height to be in contact with the inner surface of the upper case or the lower case.

6. The PCB module of claim 5, further comprising an upper insulation layer having electrical insulating properties, which is interposed between the heat dissipation plate and the upper PCB; and
a lower insulation layer having electrical insulating properties, which is interposed between the heat dissipation plate and the lower PCB.

7. The PCB module of claim 1, wherein an outer surface of at least one of the upper and lower cases has a first concavo-convex shape formed thereon, and
wherein the PCB module further comprises a heat dissipation structure which is attached to the outer surface of the at least one case and has a second concavo-convex shape to be engaged with the first concavo-convex shape.

8. A heat dissipation plate having electrical insulating properties, which is used in a multi-layer PCB assembly having a multi-surface heat dissipation structure, the heat dissipation plate comprising:
a first heat pole of a first height which protrudes from a top or bottom surface of the heat dissipation plate; and
a second heat pole of a second height which protrudes from the top or bottom surface of the heat dissipation plate,
wherein the heat dissipation plate is interposed between an upper PCB comprising a first layer circuit pattern of the multi-layer PCB assembly and a lower PCB comprising a second layer circuit pattern,
wherein the first heat pole is thermally in contact with an electronic circuit element mounted on the upper PCB or lower PCB, and
wherein the second heat pole is thermally in contact with an inner surface of a case for covering the top surface or bottom surface of the multi-layer PCB assembly.

9. The heat dissipation plate of claim 8, further comprising one or more penetration regions penetrating through the top and bottom surfaces of the heat dissipation plate, and
wherein the multi-layer PCB assembly comprises one or more contact points or contact regions where the upper PCB and the lower PCB are physically or electrically in contact with each other through the penetrating regions of the heat dissipation plate.

10. The heat dissipation plate of claim 8, wherein one or more penetrating portions are formed on at least one of the upper PCB and the lower PCB to allow the first heat pole or the second heat pole to be inserted therethrough, and
wherein the first height of the first heat pole is the same as height of the surface of the upper or lower PCB, and the second height of the second heat pole is high to be in contact with the inner surface of the case.

11. The heat dissipation plate of claim 10, wherein the first heat pole is configured to absorb heat generated from an electronic circuit element mounted on the upper or lower PCB, and the second heat pole is configured to discharge heat to the case.

12. A multi-layer PCB assembly which is used in a PCB module having a multi-surface heat dissipation structure, the multi-layer PCB assembly comprising:
an upper PCB which comprises a first layer circuit pattern of the multi-layer PCB assembly;
a lower PCB which comprises a second layer circuit pattern of the multi-layer PCB assembly; and
a heat dissipation plate having electrical insulating properties, which is interposed between the upper PCB and the lower PCB, and
wherein the heat dissipation plate comprises:
a first heat pole which is thermally in contact with an electronic circuit element mounted on the upper or lower PCB; and
a second heat pole which is thermally in contact with a surface of a case for covering the upper or lower PCB.

13. The multi-layer PCB assembly of claim 12, wherein one or more penetrating portions are formed on the upper or lower PCB to allow the first heat pole or the second heat pole to be inserted therethrough, and
wherein the first heat pole protrudes to be flush with the surface of the upper or lower PCB, and the second heat pole protrudes to have a height to be in contact with the inner surface of the case.

14. The multi-layer PCB assembly of claim 13, wherein the first heat pole is configured to absorb heat generated from an electronic circuit element mounted on the upper or lower PCB, and the second heat pole is configured to discharge heat to the case.

15. The multi-layer PCB assembly of claim 12, wherein one or more penetrating regions are formed through the top and bottom surfaces of the heat dissipation plate, and
wherein the multi-layer PCB assembly comprises one or more contact points or contact regions where the upper PCB and the lower PCB are physically or electrically in contact with each other through the penetrating regions of the heat dissipation plate.

16. The multi-layer PCB assembly of claim 12, further comprising:
an upper insulation layer having electrical insulating properties, which is interposed between the heat dissipation plate and the upper PCB; and
a lower insulation layer having electrical insulating properties, which is interposed between the heat dissipation plate and the lower PCB.
